(19) United States
(12) Patent Application Publication
(10) Pub. No.: US 2025/0169213 A1
(43) Pub. Date: May 22, 2025

(54) IMAGE SENSING DEVICE

(71) Applicant: SK hynix Inc., Icheon-si (KR)

(72) Inventor: Sung Wook CHO, Icheon-si (KR)

(21) Appl. No.: 18/632,033

(22) Filed: Apr. 10, 2024

(30) Foreign Application Priority Data
Nov. 20, 2023 (KR) 10-2023-0160644

(51) Int. Cl. H01L 27/146

(52) U.S. Cl. CPC H10F 39/8053; H10F 39/182; H10F 39/8063; H10F 39/807

(57) ABSTRACT

Image sensing devices are disclosed. In an embodiment, an image sensing device may include a substrate; a color filter formed over the substrate; first isolation regions formed at both sides of the color filter; and a microlens formed over the color filter, and a lower portion of the color filter may be formed in one region of an upper end of the substrate.

### PRIORITY CLAIM AND CROSS REFERENCE TO RELATED APPLICATION

This patent document claims the priority and benefits of Korean Patent Application No. 10-2023-0160644, filed on Nov. 20, 2023, which is incorporated by reference in its entirety as part of the disclosure of this patent document.

### TECHNICAL FIELD

Various embodiments of the disclosed technology relate to an image sensing device.

### BACKGROUND

An image sensing device refers to a semiconductor device that captures optical images and converts them into electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The image sensing device may be roughly divided into CCD (Charge Coupled Device) image sensing devices and CMOS (Complementary Metal Oxide Semiconductor) image sensing devices.

### SUMMARY

The disclosed technology can be implemented in some embodiments to provide an image sensing device that can improve the image quality by suppressing a light induced pixel stain (LIPS).

In an embodiment, an image sensing device may include: a substrate; a color filter formed over the substrate; first isolation regions formed at both sides of the color filter; and a microlens formed over the color filter. In one example, a lower portion of the color filter may be formed in one region of an upper end of the substrate.

In an embodiment, an image sensing device may include: a substrate; a color filter including: a lower portion, at least part of which is formed in an upper region of the substrate; and an upper portion formed over the substrate; first isolation regions formed at both sides of the color filter; and a microlens formed over the color filter.

In an embodiment, a boundary surface between the microlens and the color filter may be formed at a height between an upper end and a lower end of the first isolation region.

In an embodiment, the second isolation regions may be formed at both sides of the lower portion of the color filter.

In an embodiment, a groove may be formed in one region of an upper end of the substrate, and the lower portion of the color filter may be formed in the groove.

In an embodiment, at least part of the lower portion of the color filter is disposed in a groove that is formed in one region of the upper region end of the substrate.

In an embodiment, an isolation layer may be formed below the color filter.

In an embodiment, the first isolation region may include: a barrier metal layer formed over the isolation layer; and a metal layer formed over the barrier metal layer.

In an embodiment, a boundary surface between the microlens and the color filter may be formed at a height between an upper end and a lower end of the metal layer.

In an embodiment, an image sensing device may include: a substrate; a color filter formed over the substrate; a microlens formed over the color filter; and a photodiode in the substrate, and first isolation regions may be formed at both sides of an upper portion of the color filter, and second isolation regions may be formed at both sides of a lower portion of the color filter.

In an embodiment, a substrate; a color including: a lower portion, at least part of which is formed in an upper region of the substrate; and an upper portion formed over the substrate; a microlens formed over the color filter; a photodiode formed in the substrate; first isolation regions formed at both sides of the upper portion of the color filter; and second isolation regions formed at both sides of the lower portion of the color filter.

In an embodiment, at least part of the lower portion of the color filter may be formed in an upper region of the substrate.

In an embodiment, the lower portion of the color filter may be formed over the photodiode.

In an embodiment, a boundary surface between the microlens and the color filter may be formed at a height between an upper end and a lower end of the first isolation region.

In an embodiment, at least part of the lower portion of the color filter is disposed in a groove that is formed in the upper region of the substrate.

In an embodiment, an isolation layer may be formed below the color filter.

In an embodiment, the first isolation region may include: a barrier metal layer formed over the isolation layer; and a metal layer formed over the barrier metal layer.

In an embodiment, a boundary surface between the microlens and the color filter may be formed at a height between an upper end and a lower end of the metal layer.

### BRIEF DESCRIPTION OF THE DRAWINGS

FIG. 1 is a block diagram of an image sensing device based on an embodiment.

FIGS. 2 and 3 shows example structures of an image sensing device based on an embodiment.

### DETAILED DESCRIPTION

Features, and certain advantages in connection with specific implementations of the disclosed technology disclosed in this patent document are described by example embodiments with reference to the accompanying drawings.

When incident light passing through a microlens is collected, a focal point is formed on a position of a color filter, creating a spot called “void” on the color filter, which causes image quality deterioration. The disclosed technology can be implemented in some embodiments to address these issues by providing an image sensing device capable of preventing a light induced pixel stain (LIPS).

In some implementations, since the upper region of the color filter is formed between isolation regions at both sides and the lower region of the color filter is formed in one region of the substrate, a focal point is formed in the lower portion of the microlens, preventing the light induced pixel stain (LIPS) or image quality defects.

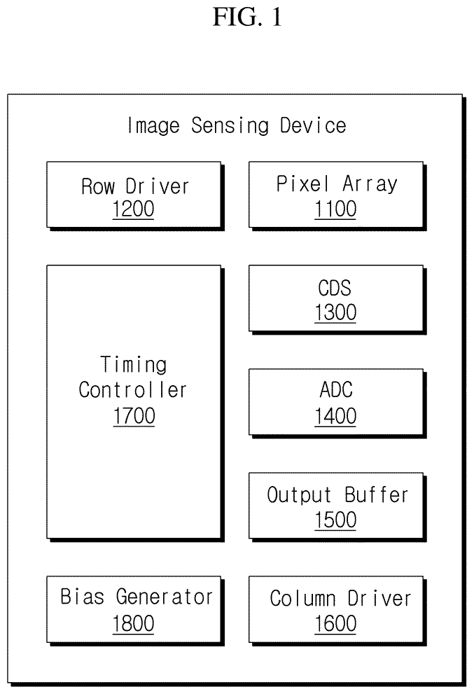

FIG. 1 is a block diagram of an image sensing device based on an embodiment.

Referring to FIG. 1, the image sensing device based on an embodiment may include a pixel array 1100, a row driver 1200, a correlated double sampler (CDS) 1300, an analog-digital converter (ADC) 1400, an output buffer 1500, a column driver 1600, a timing controller 1700, and a bias generator 1800. The components of the image sensing device illustrated are discussed by way of example only, and this patent document encompasses additions or omissions of components as necessary.

The pixel array 1100 may include a plurality of pixels arranged in a plurality of rows and a plurality of columns. In one embodiment, the plurality of pixels can be arranged in a two-dimensional pixel array including rows and columns. In another example, the plurality of unit imaging pixels can be arranged in a three-dimensional pixel array. The plurality of pixels may convert an optical signal into an electrical signal on a unit pixel basis or on a pixel group basis and the pixels in a pixel group share at least certain internal circuitry. The pixel array 1100 may receive driving signals, including a row selection signal, a pixel reset signal and a transmission signal, from the row driver 1200. Upon receiving the driving signal, corresponding pixels in the pixel array 1100 may be activated to perform operations corresponding to the row selection signal, the pixel reset signal, and the transmission signal.

The row driver 1200 may activate the pixel array 1100 to perform certain operations on the pixels in the corresponding row based on commands and control signals provided by the timing controller 1700. In one embodiment, the row driver 1200 may select at least one pixel arranged in at least one row of the pixel array 1100. The row driver 1200 may generate a row selection signal to select at least one row among the plurality of rows. The row driver 1200 may sequentially enable the pixel reset signal and the transmission signal for the pixels corresponding to the at least one selected row. Thus, a reference signal and an image signal, which are analog signals generated by each of the pixels of the selected row, may be sequentially transferred to the CDS 1300. At this time, the reference signal may be an electrical signal that is provided to the CDS 1300 when a sensing node of a pixel (e.g., floating diffusion node) is reset, and the image signal may be an electrical signal that is provided to the CDS 1300 when photocharges generated by the pixel are accumulated in the sensing node. A reference signal representing reset noise inherent in a pixel and an image signal representing intensity of incident light may be collectively referred to as a pixel signal.

CMOS image sensors may use the correlated double sampling (CDS) to remove undesired offset values of pixels known as the fixed pattern noise by sampling a pixel signal twice to remove the difference between these two samples. In some embodiments, the correlated double sampling (CDS) may remove the undesired offset value of pixels by comparing pixel output voltages obtained before and after photocharges generated by incident light are accumulated in the sensing node so that only pixel output voltages based on the incident light can be measured. In one embodiment, the CDS 1300 may sequentially sample and hold the reference signal and the image signal, which are provided to each of a plurality of column lines from the pixel array 1100. That is, the CDS 1300 may sample and hold the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 1400 is used to convert CDS signals into digital signals for each of the columns and output the digital signal. In one embodiment, the ADC 1400 may be implemented as a ramp-compare type ADC. The ramp-compare type ADC may include a comparator circuit for comparing the analog pixel signal with a ramp signal that ramps up or down over time, and a counter that counts until the ramp signal matches the analog pixel signal. In one embodiment, the ADC 1400 may convert the correlate double sampling signal generated by the CDS 1300 for each of the columns into a digital signal, and output the digital signal.

The ADC 1400 may include a plurality of column counters corresponding to each of the columns of the pixel array 1100. Each column of the pixel array 1100 is coupled to a column counter, and image data can be generated by converting the correlate double sampling signals corresponding to each of the columns into digital signals using the column counters. In another embodiment, the ADC 1400 may include a global counter to convert the correlate double sampling signals corresponding to each of the columns into digital signals using a global code provided from the global counter.

The output buffer 1500 may temporarily hold the column-based image data provided from the ADC 1400 to output the image data. The output buffer 1500 may temporarily store the image data output from the ADC 1400 based on control signals of the timing controller 1700. The output buffer 1500 may serve as an interface to compensate for data rate differences or transmission (or processing) rate differences between the image sensing device and other devices.

The column driver 1600 may select a column of the output buffer 1500 based on a control signal from the timing controller 1700, and sequentially output the image data, which are temporarily stored in the selected column of the output buffer 1500. In one embodiment, upon receiving an address signal from the timing controller 1700, the column driver 1600 may generate a column selection signal based on the address signal and select a column of the output buffer 1500, outputting the image data as an output signal from the selected column of the output buffer 1500.

The timing controller 1700 may control at least one among the row driver 1200, the CDS 1300, the ADC 1400, the output buffer 1500, the column driver 1600, and the bias generator 1800.

The timing controller 1700 may provide a clock signal required for the operations of the respective components of the image sensing device, a control signal for timing control, and address signals for selecting a row or column, a signal that controls a level of a bias voltage applied to the pixel array 1100, and the like to at least one among the row driver 1200, the CDS 1300, the ADC 1400, the output buffer 1500, the column driver 1600 and the bias generator 1800. In an embodiment of the disclosed technology, the timing controller 1700 may include a logic control circuit, a phase lock loop (PLL) circuit, a timing control circuit, a communication interface circuit and others.

The bias generator 1800 may generate a bias voltage for suppressing a dark current generated in pixels of the pixel array 1100 and supply the generated bias voltage to the pixel array 1100.

The bias voltage may be determined during a wafer probe test of the image sensing device and stored in a one-time programmable (OTP) memory. For example, the bias voltage may be experimentally determined as a value capable of maximizing a dark current suppression effect while minimizing unnecessary power consumption without impairing performance of the image sensing device.

The bias generator 1800 may generate a voltage corresponding to the bias voltage stored in the OTP memory. In an embodiment, the OTP memory may be included in the image sensing device, and in particular, may be included in the bias generator 1800.

In an embodiment, the bias voltage may have a plurality of values. In one example, the bias voltage may have one of a plurality of values at a certain timing.

In some implementations, the plurality of values may respectively correspond to a plurality of operation modes of the image sensing device. The dark current that is generated at a low light level and the dark current that is generated at a high light level may be different from each other, and in order for the bias generator 1800 to effectively suppress the dark current in each environment, the bias voltage may vary depending on the mode.

In some implementations, the plurality of values may respectively correspond to a plurality of areas of the pixel array 1100. Dark currents generated at different positions of the pixel in the pixel array 1100 may be different from each other, and in order for the bias generator 1800 to effectively suppress the dark current regardless of the position of the pixel, the bias voltage may vary depending on the area.

In one example, the bias voltage may be a negative voltage having a negative sign, but the disclosed technology is not limited thereto.

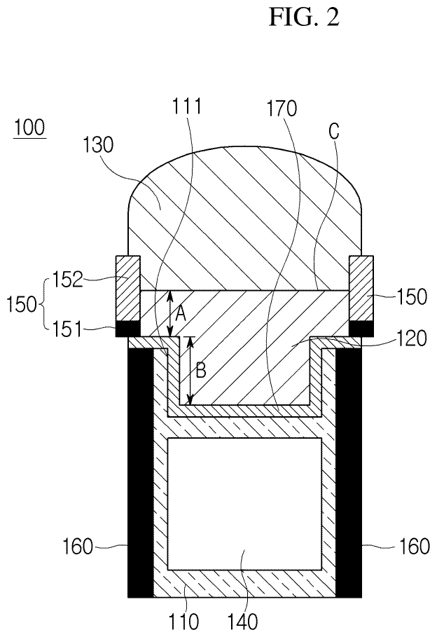

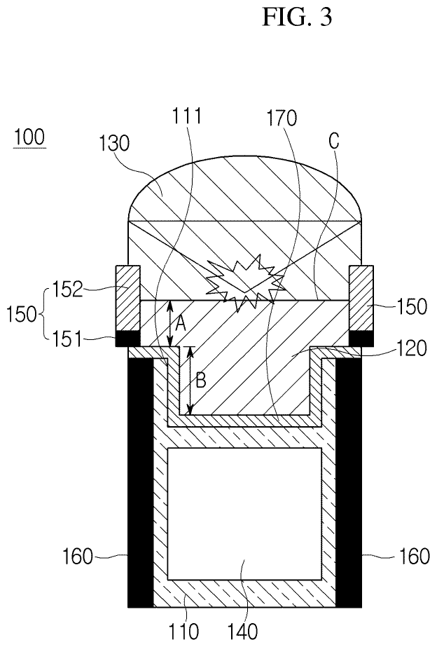

FIGS. 2 and 3 are views for describing a structure of an image sensing device based on an embodiment.

Referring to FIGS. 1 and 2, the pixel array 1100 based on an embodiment may include a plurality of unit pixels 100.

The unit pixel 100 may include a substrate 110, a color filter 120, a microlens 130, an optical detector 140, a first isolation region 150, a second isolation region 160, and an isolation layer 170. The microlens 130 and the color filter 120 are located over the optical detector 140 to direct incident light through the microlens 130 and the color filter 120 to the optical detector 140 so that only light of a certain color filtered by the color filter 120 enters the optical detector 140. The optical detector 140 operates to convert received filtered light into an optical detector signal as the pixel signal for the unit pixel 100 and may include, for example, a photodiode in some implementations.

In an embodiment, the substrate 110 may include a silicon (Si) material in a single-crystalline state.

In an embodiment, the color filter 120 may be formed over the substrate 110 to filter and pass visible light from the light incident upon the color filter 120 through the microlens 130. In an embodiment, the color filter 120 may include one of a blue color filter, a green color filter, and a red color filter. Here, the blue color filter passes blue light and block other wavelengths of the visible light, the green color filter passes green light and block other wavelengths of the visible light, and the red color filter passes red light and block other wavelengths of the visible light.

In some embodiments of the disclosed technology, the color filter 120 may include an upper portion A and a lower portion B.

In an embodiment, at least part of the lower portion B of the color filter 120 may be formed in an upper region (e.g., upper end) of the substrate 110. In one example, as shown in FIG. 3, a lower part of the lower portion B of the color filter 120 may be formed in the upper portion of the substrate 110.

In an embodiment, a groove 111 is formed in the upper region of the substrate 110. In one example, the groove 111 is formed by etching the upper region of the substrate 110. In an embodiment, the lower portion B of the color filter 120 may be formed in the groove 111 of the substrate 110. The lower portion B of the color filter 120 may be formed in the groove 111 in the upper region of the substrate 110.

In an embodiment, the lower portion B of the color filter 120 may be formed over the photodiode 140.

In an embodiment, the upper portion A of the color filter 120 may be formed between the first isolation regions 150. In one example, the first isolation regions 150 is formed to protrude from the upper surface of the color filter 120 toward the microlens 130 disposed over the color filter 120.

In an embodiment, a boundary surface C between the microlens 130 and the color filter 120 may be formed between an upper end and a lower end of the first isolation region 150.

In an embodiment, the lower portion B of the color filter 120 may be formed between the second isolation regions 160.

In some embodiments, the depth of the upper portion A of the color filter 120 is the same as the depth of the lower portion B of the color filter 120. In some embodiments, the depth of the upper portion A of the color filter 120 is different from the depth of the lower portion B of the color filter 120. In one example, the depth of the lower portion B of the color filter 120 is deeper than the depth of the upper portion A of the color filter 120. In another example, the depth of the upper portion A of the color filter 120 is deeper than the depth of the lower portion B of the color filter 120.

Since the boundary surface C, which is a boundary between the microlens 130 and the color filter 120, is formed at a height between the upper end and the lower end of the first isolation region 150, and the lower portion B of the color filter 120 is formed in the upper region of the substrate 110, a focal point may be formed in a lower portion of the microlens 130, rather than in the color filter 120, thereby preventing a spot called “void” from being created in the color filter 120.

The microlens 130 may be formed over the color filter 120, and may serve to collect the light incident upon the microlens 130 from the outside.

The photodiode 140 may be formed in an inner region of the substrate 280, and a n-type impurity region and a p-type impurity region may be vertically stacked in the photodiode 140. The n-type impurity region and the p-type impurity region may be formed through an ion injection process.

The first isolation region 150 may be formed at both sides of the upper portion A of the color filter 120.

In an embodiment, the first isolation region 150 may include a barrier metal layer 151 and a metal layer 152.

In an embodiment, the barrier metal layer 151 may be formed over the isolation layer 170, and may include a titanium nitride layer (TiN).

In an embodiment, the metal layer 152 may be formed over the barrier metal layer 151, and may include tungsten (W).

In an embodiment, the boundary surface C between the microlens 130 and the color filter 120 may be formed between the upper end and the lower end of the metal layer 152.

In an embodiment, the first isolation region 150 may include an air layer (not illustrated).

In an embodiment, the second isolation region 160 may be formed at both sides of the lower portion B of the color filter 120.

The second isolation region 160 may be formed in a vertically deep groove to prevent a crosstalk among neighboring sub-pixels 200, and may be formed through a deep trench isolation (DTI) process.

The second isolation region 160 may include at least one of a silicon oxynitride (SiON) layer, a silicon oxide (SiO) layer, or a silicon nitride (SiN) layer.

The second isolation region 160 may be formed at both sides of the photodiode 140.

The second isolation region 160 may be formed at both sides of the lower portion B of the color filter 120.

The isolation layer 170 may be formed below the color filter 120.

In an embodiment, the isolation layer 170 may include at least one of an oxide layer, a nitride layer, or an oxynitride layer.

In some embodiments of the disclosed technology, since the boundary surface C between the microlens 130 and the color filter 120 is formed at a height between the upper end and the lower end of the first isolation region 150, and the lower portion B of the color filter 120 is formed in a region of an upper end of the substrate 110, a focal point may be formed in a lower portion of the microlens 130, rather than in the color filter 120, thereby preventing a spot called “void” in the color filter 120.

In addition, the upper region of the color filter is formed between isolation regions disposed at both sides and the lower portion of the color filter is formed in a region of the upper end of the substrate, and accordingly a focal point is formed in the lower portion of the microlens, rather than in the color filter, thereby preventing image quality deterioration associated with the light induced pixel stain (LIPS).

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. An image sensing device, comprising:
a substrate;
a color filter formed over the substrate;
first isolation regions formed at both sides of the color filter; and
a microlens formed over the color filter,
wherein a lower portion of the color filter is formed in one region of an upper end of the substrate.

2. The image sensing device of claim 1,
wherein a boundary surface between the microlens and the color filter is formed at a height between an upper end and a lower end of the first isolation region.

3. The image sensing device of claim 1, further comprising:
second isolation regions formed at both sides of the lower portion of the color filter.

4. The image sensing device of claim 1,
wherein at least part of the lower portion of the color filter is disposed in a groove that is formed in the upper region of the substrate.

5. The image sensing device of claim 1, further comprising:
an isolation layer formed below the color filter.

6. The image sensing device of claim 5,
wherein the first isolation region comprises:
a barrier metal layer formed over the isolation layer; and
a metal layer formed over the barrier metal layer.

7. The image sensing device of claim 6,
wherein a boundary surface between the microlens and the color filter is formed at a height between an upper end and a lower end of the metal layer.

8. An image sensing device, comprising:
a substrate;
a color filter formed over the substrate;
a microlens formed over the color filter;
a photodiode formed in the substrate;
first isolation regions formed at both sides of an upper portion of the color filter; and
second isolation regions formed at both sides of a lower portion of the color filter.

9. The image sensing device of claim 8,
wherein at least part of the lower portion of the color filter is formed in an upper region of the substrate.

10. The image sensing device of claim 9,
wherein the lower portion of the color filter is formed over the photodiode.

11. The image sensing device of claim 9,
wherein a boundary surface between the microlens and the color filter is formed at a height between an upper end and a lower end of the first isolation region.

12. The image sensing device of claim 9,
wherein at least part of the lower portion of the color filter is disposed in a groove that is formed in the upper region of the substrate.

13. The image sensing device of claim 9, further comprising:
an isolation layer formed below the color filter.

14. The image sensing device of claim 13,
wherein the first isolation region comprises:
a barrier metal layer formed over the isolation layer; and
a metal layer formed over the barrier metal layer.

15. The image sensing device of claim 14,
wherein a boundary surface between the microlens and the color filter is formed at a height between an upper end and a lower end of the metal layer.
